(19) United States
(12) Patent Application Publication
(10) Pub. No.: US 2012/0070985 A1
(43) Pub. Date: Mar. 22, 2012

(54) EXPOSURE METHOD AND METHOD FOR MANUFACTURING SEMICONDUCTOR DEVICE

(76) Inventors: Takaki Hashimoto, Kanagawa-ken (JP); Kazuya Fukuhara, Tokyo (JP); Toshiya Kotani, Tokyo (JP); Yasunobu Kai, Kanagawa-ken (JP)

(21) Appl. No.: 13/233,971

(22) Filed: Sep. 15, 2011

(30) Foreign Application Priority Data
Sep. 17, 2010 (JP) 2010-210125

(51) Int. Cl. H01L 21/768; G03B 27/32

(52) U.S. Cl. 438/675; 355/77; 257/E21.586

(57) ABSTRACT

According to one embodiment, an exposure method is disclosed. The method can include applying light to a photomask by an illumination. The method can include converging diffracted beams emitted from the photomask by a lens. In addition, the method can include imaging a plurality of point images on an exposure surface. On the photomask, a light transmitting region is formed at a lattice point represented by nonorthogonal unit cell vectors, and in the illumination, a light emitting region is set so that three or more of the diffracted beams pass through positions equidistant from center of a pupil of the lens.

### CROSS-REFERENCE TO RELATED APPLICATIONS

This application is based upon and claims the benefit of priority from the prior Japanese Patent Application No. 2010-210125, filed on Sep. 17, 2010; the entire contents of which are incorporated herein by reference.

### FIELD

Embodiments described herein relate generally to an exposure method and a method for manufacturing a semiconductor device.

### BACKGROUND

The finest pattern in a NAND flash memory is the pattern of bit line contacts (CB) each connected to a bit line. The miniaturization of bit lines makes it difficult to form this bit line contact. Thus, a technique has been proposed in which the position of the bit line contact in the extending direction of the bit line is slightly shifted for each bit line. Hence, while maintaining the minimum distance between the bit line contacts at a certain value or more, the arrangement pitch of the bit lines can be reduced. However, in a NAND flash memory, there is demand for further reducing the arrangement pitch of the bit lines to increase the packing density.

### BRIEF DESCRIPTION OF THE DRAWINGS

FIG. 1 is a plan view illustrating the layout of contacts in a semiconductor device of a first embodiment;

FIG. 2 is a schematic plan view illustrating a method for describing the modified n-run stagger;

FIG. 3 is a process sectional view illustrating a method for manufacturing the semiconductor device according to the first embodiment;

FIG. 4 is an optical model diagram illustrating an exposure optical system in the first embodiment;

FIG. 5 is a view illustrating an illumination geometry in the exposure optical system of the first embodiment;

FIG. 6 is a view illustrating another illumination geometry in the exposure optical system of the first embodiment;

FIG. 7 is a view illustrating still another illumination geometry in the exposure optical system of the first embodiment;

FIG. 8 shows uniquely occurring combinations of the parameters n and m;

FIG. 9A illustrates a reference example of an illumination condition, and FIG. 9B illustrates the distribution of diffracted beams formed when the photomask of the modified n-run stagger is irradiated with the light shown in FIG. 9A;

FIG. 10A illustrates an illumination condition of the first embodiment, and FIG. 10B illustrates the distribution of diffracted beams formed when the photomask of the modified n-run stagger is irradiated with the light shown in FIG. 10A;

FIG. 11 illustrates the interference state resulting from three diffracted beams;

FIG. 12A illustrates another illumination condition of the first embodiment, and FIG. 12B illustrates the distribution of diffracted beams formed when the photomask of the n-run stagger is irradiated with the light shown in FIG. 12A;

FIG. 13A illustrates still another illumination condition of the first embodiment, and FIG. 13B illustrates the distribution of diffracted beams formed when the photomask of the n-run stagger is irradiated with the light shown in FIG. 13A;

FIG. 14A illustrates an illumination condition of a second embodiment, and FIG. 14B illustrates the distribution of diffracted beams formed when the photomask of the modified n-run stagger is irradiated with the light shown in FIG. 14A;

FIG. 15 illustrates an illumination geometry in an exposure optical system of the second embodiment; and

FIGS. 16A to 16C illustrate other illumination geometries in the exposure optical system of the second embodiment.

### DETAILED DESCRIPTION

In general, according to one embodiment, an exposure method is disclosed. The method can include applying light to a photomask by an illumination. The method can include converging diffracted beams emitted from the photomask by a lens. In addition, the method can include imaging a plurality of point images on an exposure surface. On the photomask, a light transmitting region is formed at a lattice point represented by nonorthogonal unit cell vectors, and in the illumination, a light emitting region is set so that three or more of the diffracted beams pass through positions equidistant from center of a pupil of the lens.

In general, according to one embodiment, an exposure method is disclosed. The method can include applying light to a photomask by an illumination. The method can include converging diffracted beams emitted from the photomask by a lens. In addition, the method can include imaging a plurality of point images on an exposure surface. On the photomask, a light transmitting region is formed at a lattice point represented by nonorthogonal unit cell vectors, and in the illumination, a light emitting region is set so that two or more pairs of the diffracted beams are incident on a pupil of the lens and that the two diffracted beams belonging to each of the pairs pass through positions equidistant from center of the pupil of the lens.

In general, according to one embodiment, a method is disclosed for manufacturing a semiconductor device. The method can include forming an interlayer insulating film on a substrate. The method can include forming a resist film on the interlayer insulating film. The method can include performing exposure on the resist film and developing the resist film. The method can include forming a contact hole in the interlayer insulating film by etching using the developed resist film as a mask. In addition, the method can include forming a contact by burying a metal in the contact hole. The exposure is performed by the exposure method described above, and each of the point images is a region where the contact hole is to be formed.

Various embodiments will be described hereinafter with reference to the accompanying drawings.

First, a first embodiment is described.

To begin with, a semiconductor device to be manufactured in the embodiment is described.

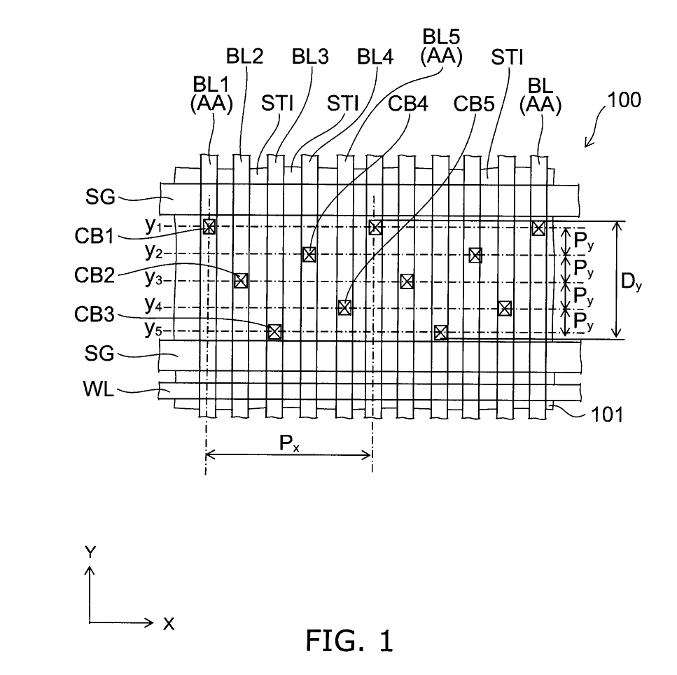

FIG. 1 is a plan view illustrating the layout of contacts in the semiconductor device of the embodiment.

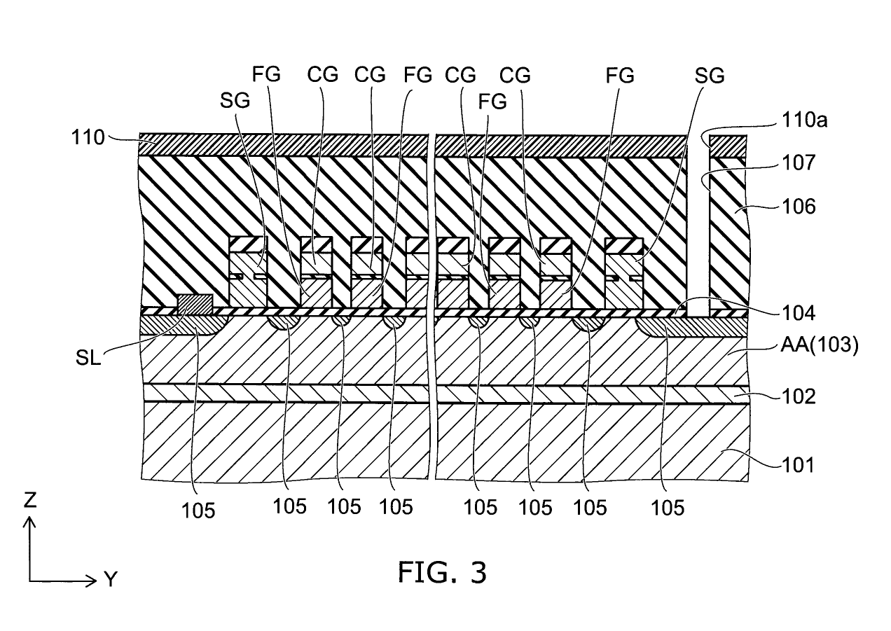

As shown in FIG. 1, the semiconductor device to be manufactured in the embodiment is a NAND flash memory 100. In the NAND flash memory 100, a plurality of device isolation insulators STI are provided on a silicon substrate 101. An active area AA is formed between the device isolation insulators STI. A bit line BL is provided immediately above the active area AA. In the following, the extending direction of the device isolation insulator STI, the active area AA, and the bit line BL is referred to as “Y direction”. Among the directions parallel to the upper surface of the silicon substrate 101, the direction orthogonal to the Y direction is referred to as “X direction”. The direction perpendicular to the upper surface of the silicon substrate 101 is referred to as “Z direction”. Above the active area AA, a select gate electrode SG, a word line WL, and a source line SL (see FIG. 3) extending in the X direction are provided.

In the region sandwiched between the select gate electrodes SG where the word line WL and the source line SL are not located, a bit line contact CB is provided. The bit line contact CB is connected between one active area AA and one bit line BL located immediately thereabove. The bit line contact CB is formed in an interlayer insulating film 104 (see FIG. 3) provided above the silicon substrate 101.

As viewed in the Z direction, the bit line contacts CB are located at part of the lattice points of a lattice extending in the X and Y directions, in units of five bit lines BL1-BL5 being consecutively arranged. The positions in the Y direction of the bit line contacts CB1-CB5 respectively connected to the bit lines BL1-BL5 are different from each other. The bit line contacts CB1-CB5 are not arranged in a line.

Specifically, for Y coordinates y₁-y₅ equally spaced along the Y direction, the Y coordinate of the bit line contact CB1 connected to the first bit line BL1 is y₁. The Y coordinate of the bit line contact CB2 connected to the second bit line BL2 is y₃. The Y coordinate of the bit line contact CB3 connected to the third bit line BL3 is y₅. The Y coordinate of the bit line contact CB4 connected to the fourth bit line BL4 is y₂. The Y coordinate of the bit line contact CB5 connected to the fifth bit line BL5 is y₄. Thus, the arrangement order in the X direction of the bit line contacts CB is not matched with the arrangement order in the Y direction. Hence, without increasing the length D_{y} of the layout region of the bit line contacts CB, while ensuring the minimum distance between the bit line contacts CB at a certain value or more, the arrangement pitch of the bit lines BL can be reduced.

Thus, in this contact layout, five bit lines BL constitute one unit in which the arrangement order in the X direction of the bit line contacts CB is not matched with the arrangement order in the Y direction. In the following, such a contact layout is referred to as “modified 5-run stagger”. Here, the number of bit lines BL constituting one unit of the contact layout is not limited to five. When the number of bit lines BL consecutively arranged and constituting one unit of the contact layout is n (where n is an integer of 2 or more), such a contact layout is referred to as “modified n-run stagger”.

The “modified n-run stagger” can be generally described as follows.

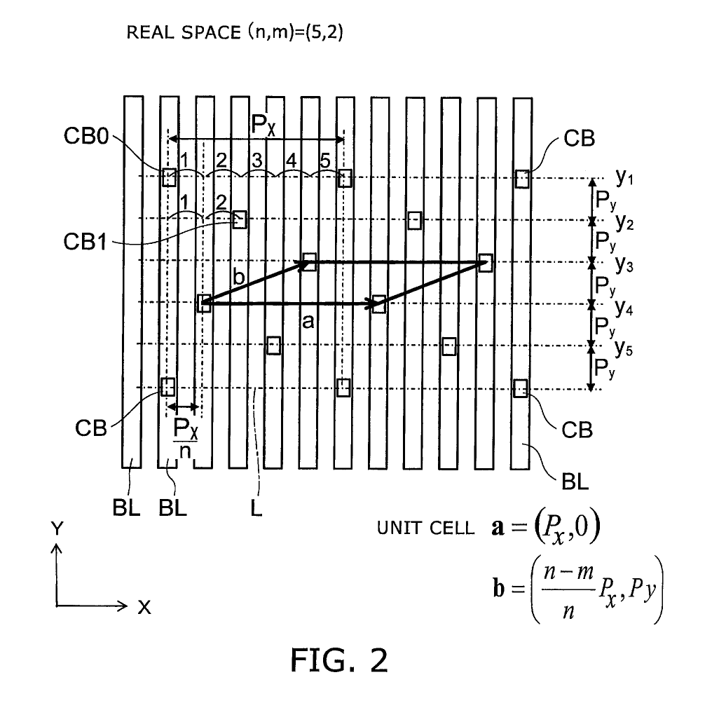

FIG. 2 is a schematic plan view illustrating the method for describing the modified n-run stagger.

First, it is assumed that the number of bit lines BL consecutively arranged and constituting one unit of the contact layout is n. In the example shown in FIG. 2, n=5. Furthermore, as shown in FIG. 2, the arrangement pitch of the bit line contacts CB in the X direction is denoted by Pₓ. That is, among the bit line contacts CB located at an equal position in the Y direction, the distance between the adjacent bit line contacts CB is denoted by Pₓ. Here, between these bit line contacts CB, (n−1) bit lines BL are arranged. Thus, the arrangement pitch of the bit lines BL in the X direction is Pan.

On the other hand, the arrangement pitch of all the bit line contacts CB projected on a line extending in the Y direction is denoted by P_{y}. That is, the distance between the Y coordinates y₁ and y₂ is denoted by P_{y}. The bit line contacts CB are located at part of the lattice points of a lattice L extending in the X and Y directions. The pitch in the X direction of the lattice L is Pₓ/n, equal to the arrangement pitch of the bit lines BL. The pitch in the Y direction of the lattice L is P_{y}. As viewed from one bit line contact CB0 with Y coordinate y₁, among the bit line contacts CB located at coordinate y₂ displaced by one pitch P_{y} in the Y direction, the nearest to the bit line contact CB0 is referred to as bit line contact CB1. Then, the bit line contact CB1 is connected to the m-th bit line BL as viewed from the bit line BL connected with the bit line contact CB0, where m is a natural number of n or less. In the example shown in FIG. 2, m=2.

Thus, the modified n-run stagger can be described by the two variables n and m. In the example shown in FIG. 2, (n, m)=(5, 2). Furthermore, the modified n-run stagger can also be described by a unit cell composed of nonorthogonal unit vectors a and b. An arbitrary lattice point R can be represented as R=ia+jb. For instance, a=(Pₓ, 0), b=((n−m)/n×Pₓ, P_{y}), and i, j are integers. Furthermore, a is defined as a=m/n. Here, a is a real number greater than 0 and less than 1. Then, b=((1−a)×Pₓ, P_{y}). Furthermore, the distance between the bit line contact CB0 and the bit line contact CB1 in the X direction is a×Pₓ.

Next, a method for manufacturing a semiconductor device according to the embodiment is described.

The method for manufacturing a semiconductor device according to the embodiment is a method for manufacturing the aforementioned NAND flash memory 100.

FIG. 3 is a process sectional view illustrating the method for manufacturing a semiconductor device according to the embodiment.

First, as shown in FIG. 3, a silicon substrate 101 is prepared. Next, impurity is ion implanted into an upper portion of the silicon substrate 101 to form an n-type well 102. Next, impurity is ion implanted into an upper portion of the n-type well 102 to form a p-type well 103. Next, a plurality of trenches extending in the Y direction are formed in the p-type well 103. Silicon oxide is buried in this trench to form a device isolation insulator STI (see FIG. 1). Here, the portion of the p-type well 103 between the device isolation insulators STI constitutes an active area AA extending in the Y direction.

Next, an insulating film 104 is formed above the silicon substrate 101. Floating gate electrodes FG are formed in a matrix configuration immediately above the respective active areas AA. Word lines WL and select gate electrodes SG extending in the X direction are formed thereon. Next, impurity is implanted using the word line WL and the select gate electrode SG as a mask to form an n-type diffusion region 105 in an upper portion of the p-type well 103. Next, a source line SL extending in the X direction is formed so as to be connected to the n-type diffusion region 105. Next, an interlayer insulating film 106 is formed above the silicon substrate 101 so as to cover the floating gate electrodes FG, the word lines WL, and the select gate electrodes SG. Next, a resist film 110 is formed on the interlayer insulating film 106.

Next, the resist film 110 is subjected to exposure so that a point image is resolved at a position where a bit line contact CB is to be formed. The method for this exposure will be described later. Next, the resist film 110 is developed. Thus, an opening 110a is formed at the portion of the resist film 110 where the point image is resolved. Next, the resist film 110 is used as a mask to perform etching. Thus, a contact hole 107 reaching the active area AA is formed in the interlayer insulating film 106. Next, a metal is buried in the contact hole 107 to form a bit line contact CB (see FIG. 1). Next, bit lines BL (see FIG. 1) extending in the Y direction are formed immediately above the active areas AA on the interlayer insulating film 106. Each bit line BL is connected to the associated active area AA through the associated bit line contact CB. Thus, a NAND flash memory 100 is manufactured.

Next, an exposure method according to the embodiment is described.

The exposure method according to the embodiment is an exposure method for realizing the aforementioned contact layout of the modified n-run stagger.

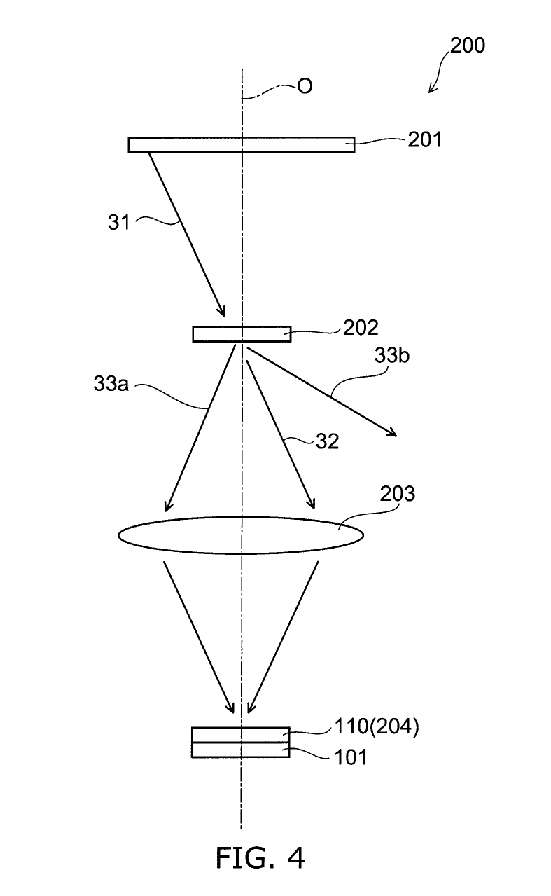

FIG. 4 is an optical model diagram illustrating an exposure optical system in the embodiment.

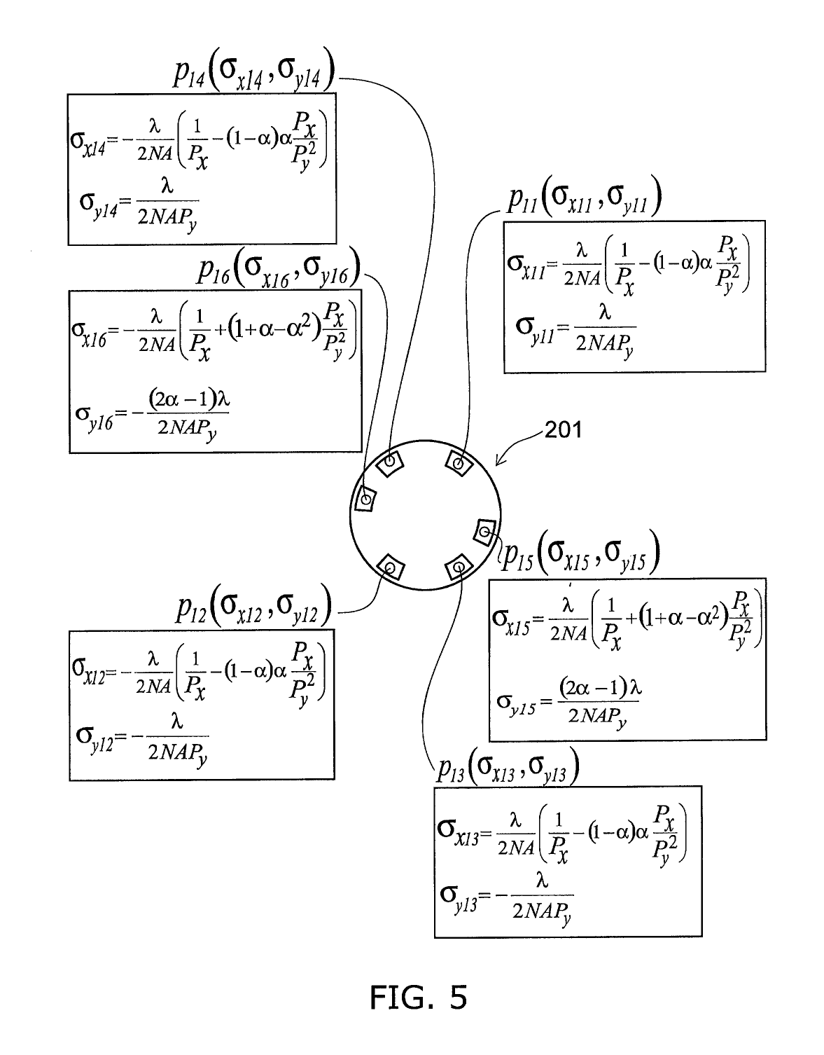

FIGS. 5 to 7 illustrate illumination geometries in the exposure optical system of the embodiment.

As shown in FIG. 4, in the exposure optical system 200 used in the embodiment, along the optical axis O, an illumination 201, a photomask 202, a lens 203, and an exposure target 204 are placed in this order. On the photomask 202 is formed a pattern corresponding to the resist pattern to be formed, i.e., a pattern corresponding to the aforementioned modified n-run stagger. That is, on the photomask 202, a light transmitting region is formed at lattice points represented as “R=ia+jb” by nonorthogonal unit cell vectors a, b. Furthermore, as an exposure target 204, the resist film 110 formed on the silicon substrate 101 is placed. The photomask 202 and the exposure target 204 are optically conjugate with each other with respect to the lens 203.

As shown in FIG. 5, in the illumination 201, a light emitting region is placed in a region including one or more points selected from the group consisting of point p11(σₓ₁₁, σ_{y11}), point p12(σₓ₁₂, Γ_{y12}), point p13(σₓ₁₃, σ_{y13}), point p14(σₓ₁₄, σ_{y14}), point p15(σₓ₁₅, σ_{y15}), and point p16(σₓ₁₆, σ_{y16}). The wavelength of light used for exposure is denoted by λ, and the numerical aperture of the lens 203 used for exposure is denoted by NA. Then, each coordinate of points p11-p16 is given by the following equations (1)-(12). As described above, a=m/n. Point p11 and point p12 are located symmetrically with each other with respect to the optical axis O (see FIG. 4). Likewise, point p13 and point p14 are also located symmetrically with each other with respect to the optical axis O. Point p15 and point p16 are also located symmetrically with each other with respect to the optical axis O.

$$\begin{matrix}{σ}_{x 11} = \frac{λ}{2 NA} ( \frac{1}{{P}_{x}} - ( 1 - α ) α \frac{{P}_{x}}{{P}_{y}^{2}} ) & ( 1 ) \\ {σ}_{y 11} = \frac{λ}{2 {NAP}_{y}} & ( 2 ) \\ {σ}_{x 12} = - \frac{λ}{2 NA} ( \frac{1}{{P}_{x}} - ( 1 - α ) α \frac{{P}_{x}}{{P}_{y}^{2}} ) & ( 3 ) \\ {σ}_{{y}_{12}} = - \frac{λ}{2 {NAP}_{y}} & ( 4 ) \\ {σ}_{x 13} = \frac{λ}{2 NA} ( \frac{1}{{P}_{x}} - ( 1 - α ) α \frac{{P}_{x}}{{P}_{y}^{2}} ) & ( 5 ) \\ {σ}_{y 13} = - \frac{λ}{2 {NAP}_{y}} & ( 6 ) \\ {σ}_{x 14} = - \frac{λ}{2 NA} ( \frac{1}{{P}_{x}} - ( 1 - α ) α \frac{{P}_{x}}{{P}_{y}^{2}} ) & ( 7 ) \\ {σ}_{y 14} = \frac{λ}{2 {NAP}_{y}} & ( 8 ) \\ {σ}_{x 15} = \frac{λ}{2 NA} ( \frac{1}{{P}_{x}} + ( 1 + α - {α}^{2} ) \frac{{P}_{x}}{{P}_{y}^{2}} ) & ( 9 ) \\ {σ}_{y 15} = \frac{( 2 α - 1 ) λ}{2 {NAP}_{y}} & ( 10 ) \\ {σ}_{x 16} = - \frac{λ}{2 NA} ( \frac{1}{{P}_{x}} + ( 1 + α - {α}^{2} ) \frac{{P}_{x}}{{P}_{y}^{2}} ) & ( 11 ) \\ {σ}_{y 16} = - \frac{( 2 α - 1 ) λ}{2 {NAP}_{y}} & ( 12 )\end{matrix}$$

Here, even if the light emitting region is a single region including one of points p11-p16, exposure of the modified n-run stagger can be realized. However, for a contact hole having a relatively large diameter and formed without using interference, such as a contact hole for the contact connected to a wiring other than the bit line, if the illumination layout is asymmetric with respect to the optical axis O, the shape of the contact hole is made asymmetric in the case of defocusing. Furthermore, if the light emitting region is a single region, energy concentrates on one location in the exposure optical system 200, which is undesirable. Thus, to enhance the symmetry of the image resolved on the exposure target 204 and alleviate the concentration of energy, it is preferable that the light emitting regions be located symmetrically with respect to the optical axis O. That is, the light emitting regions are preferably all the regions belonging to one or more pairs among the pair of the region including point p11 and the region including point p12, the pair of the region including point p13 and the region including point p14, and the pair of the region including point p15 and the region including point p16.

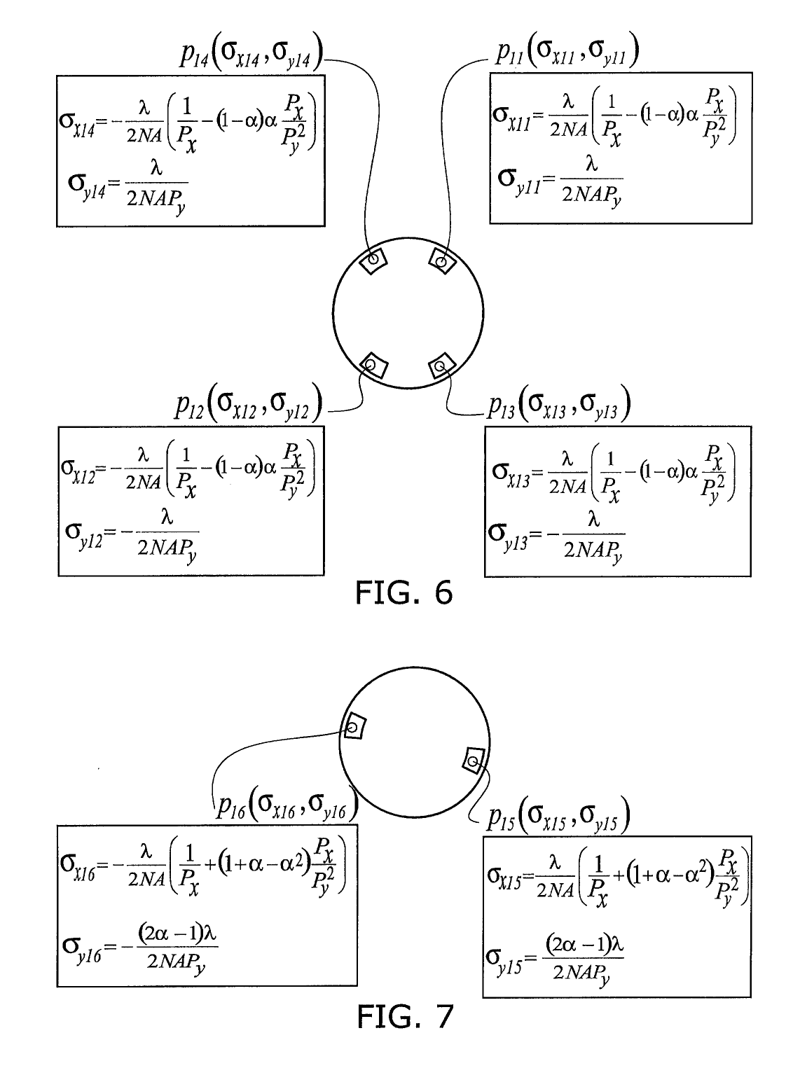

Specifically, as shown in FIG. 5, it is possible to use an illumination geometry in which the light emitting regions are located in all the six regions respectively including points p11-p16. Alternatively, as shown in FIG. 6, it is possible to use a quadrupole illumination geometry in which the light emitting regions are located in the four regions respectively including points p11-p14. Alternatively, as shown in FIG. 7, it is possible to use a dipole illumination geometry in which the light emitting regions are located in the two regions respectively including point p15 and point p16.

Such an exposure optical system 200 is used to perform exposure on the resist film 110.

First, as shown in FIG. 4, light 31 is applied from the illumination 201 toward the photomask 202. Here, in FIG. 4, the light 31 emitted from the illumination 201 is represented by one line. However, as described above, the emission light from the illumination 201 is emitted from up to six regions. The light 31 is diffracted by the pattern formed on the photomask 202. Here, FIG. 4 shows only the zeroth order diffracted beam 32 and first order diffracted beams 33a and 33b. On the lens 203, the zeroth order diffracted beam 32 and the first order diffracted beam 33a are incident. The zeroth order diffracted beam 32 and the first order diffracted beam 33a incident on the lens 203 are converged by the lens 203 and reach the resist film 110, where the beams interfere with each other and image a plurality of point images. Thus, the resist film 110 is subjected to selective exposure.

Next, combinations of the parameters n and m representing the modified n-run stagger are examined.

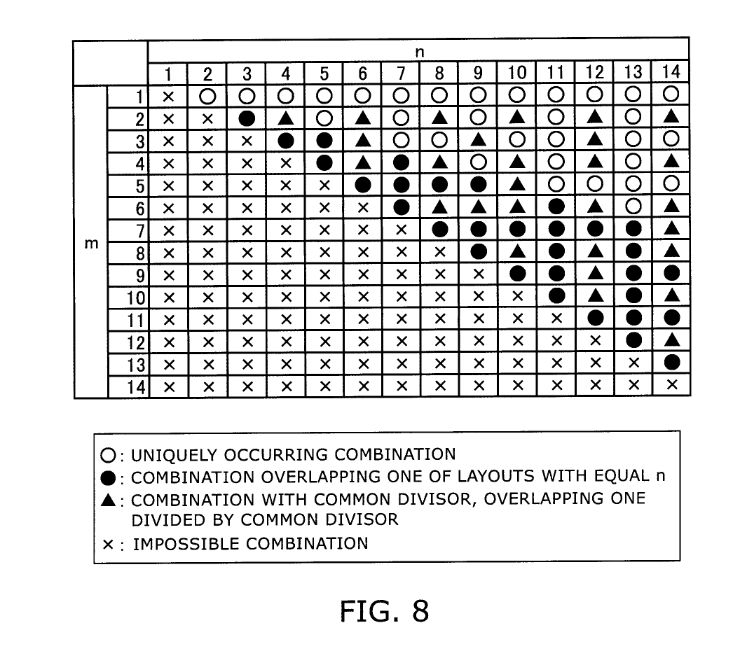

FIG. 8 shows uniquely occurring combinations of the parameters n and m.

As described above, n is the number of bit lines BL constituting one unit of the contact layout, where n is a natural number. Furthermore, m is the number of bit lines BL representing the distance in the X direction between one bit line contact CB and another bit line contact CB displaced by one pitch in the Y direction, where m is an integer of 1 or more and less than n.

As indicated by “x” in FIG. 8, by the definition of m, there occurs no combination with the value of m equal to or more than the value of n. Furthermore, as indicated by the filled triangle in FIG. 8, the combination of n and m with their values having a common divisor overlaps the combination with the values of n and m divided by the common divisor. Hence, although such a combination occurs, it is not unique. For instance, as compared with the contact layout of (n, m)=(2, 1), the contact layout of (n, m)=(4, 2) is different in the relationship with the bit line BL, but the layout of contacts themselves is geometrically similar. Furthermore, as indicated by “” in FIG. 8, the combination with the value of m greater than half the value of n is obtained by horizontally inverting one of the combinations with the value of m less than half the value of n. Hence, although such a combination occurs, it is not unique. For instance, the contact layout of (n, m)=(3, 2) is obtained by inverting the contact layout of (n, m)=(3, 1) with respect to the X direction. Thus, the uniquely occurring combinations of (n, m) are combinations indicated by “o” in FIG. 8. Hence, if the relationship with the bit line BL is not taken into consideration and the orientations in the X direction are not distinguished, then m can be defined as “an integer of 1 or more and n/2 or less not having a common divisor with n” to reduce the number of combinations of (n, m).

In the following, the process of deriving the aforementioned equations is described.

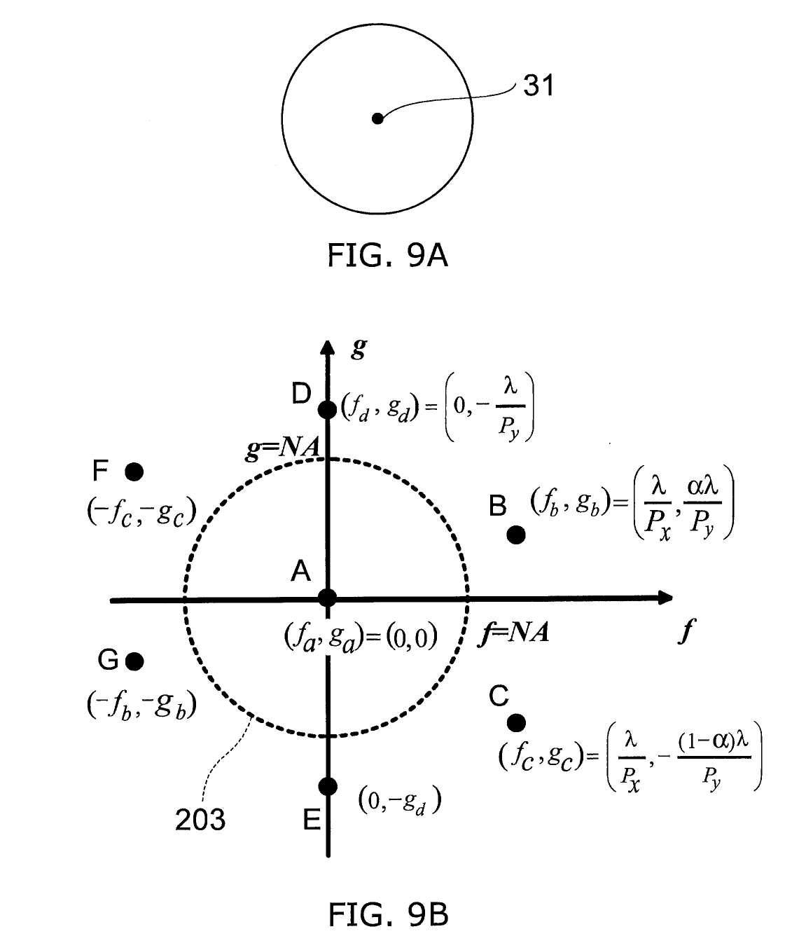

FIG. 9A illustrates a reference example of the illumination condition. FIG. 9B illustrates the distribution of diffracted beams formed when the photomask of the modified n-run stagger is irradiated with the light shown in FIG. 9A.

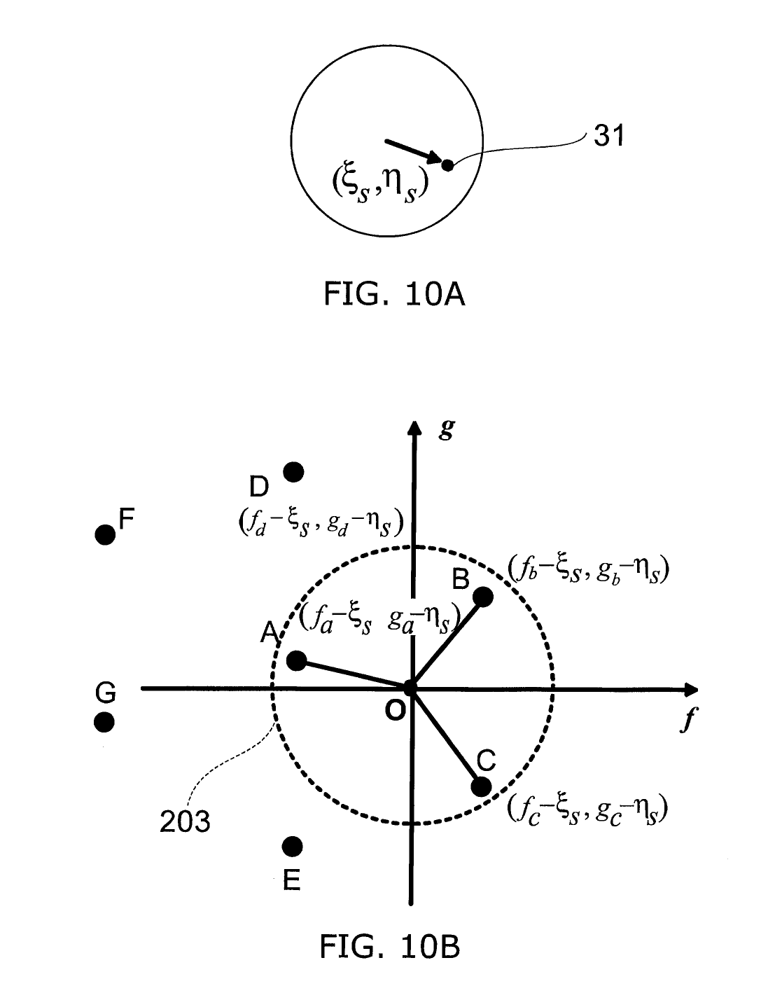

FIG. 10A illustrates an illumination condition of the embodiment. FIG. 10B illustrates the distribution of diffracted beams formed when the photomask of the modified n-run stagger is irradiated with the light shown in FIG. 10A.

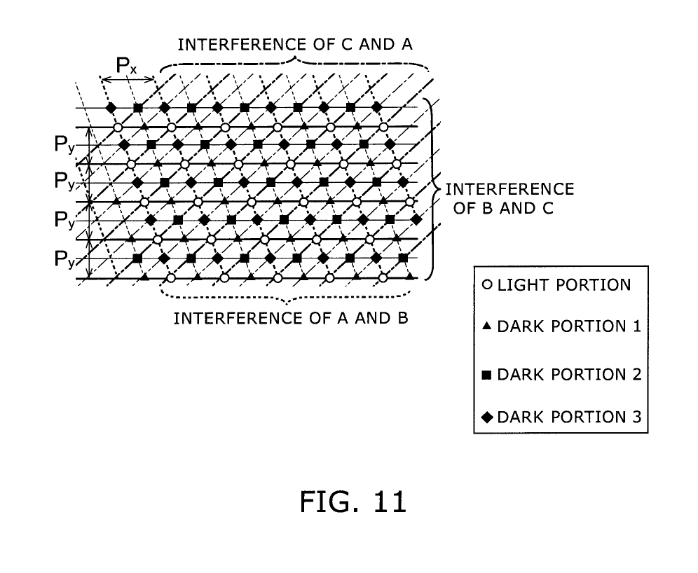

FIG. 11 illustrates the interference state resulting from three diffracted beams.

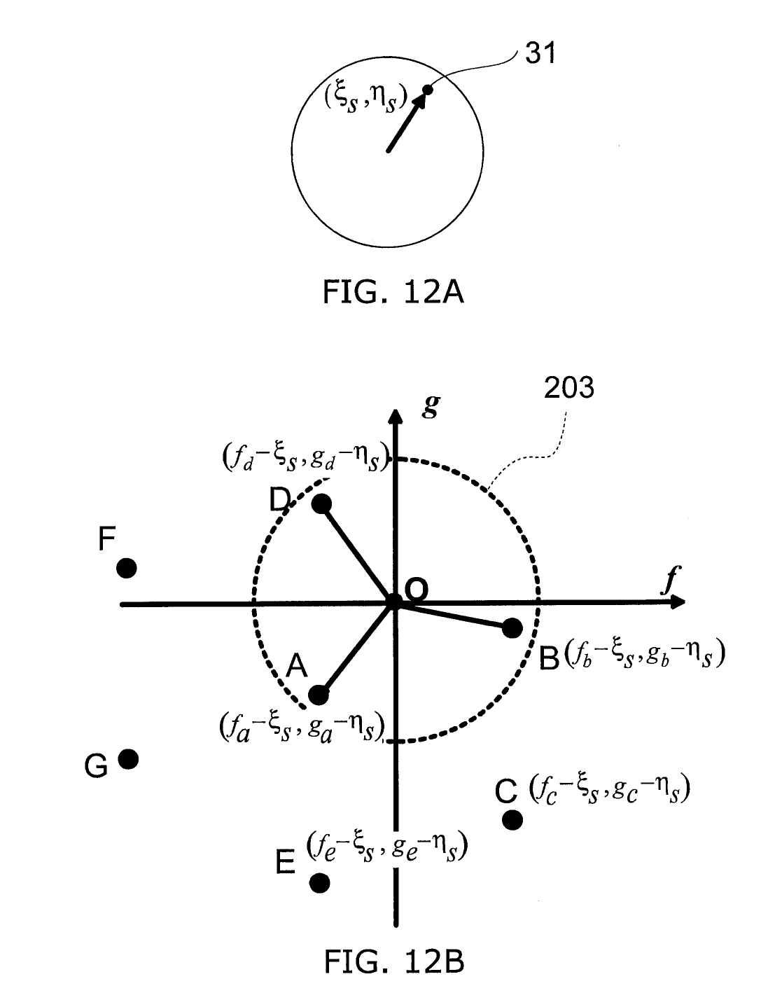

FIG. 12A illustrates another illumination condition of the embodiment. FIG. 12B illustrates the distribution of diffracted beams formed when the photomask of the n-run stagger is irradiated with the light shown in FIG. 12A.

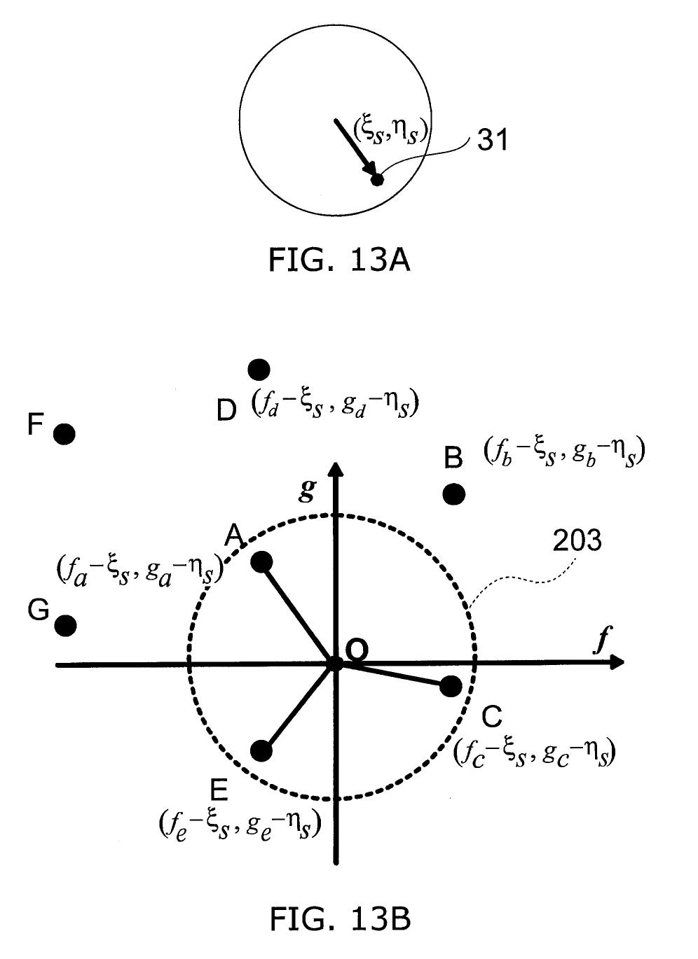

FIG. 13A illustrates still another illumination condition of the embodiment. FIG. 13B illustrates the distribution of diffracted beams formed when the photomask of the n-run stagger is irradiated with the light shown in FIG. 13A.

As shown in FIGS. 4 and 9A, light 31 is applied along the optical axis O from the illumination 201 to the photomask 202. Here, a pattern corresponding to the modified 5-run stagger as shown in FIG. 2 is formed on the photomask 202. Hence, at the pupil plane of the lens 203, as shown in FIG. 9B, one zeroth order diffracted beam A and six first order diffracted beams B-G are generated. FIG. 9B shows the frequency space. The distribution of diffracted beams shown in FIG. 9B can be obtained by Fourier transforming the figure shown in FIG. 2. This also applies to FIGS. 10B, 12B, and 13B described later. The dashed circle shown in FIGS. 9B, 10B, 12B, and 13B represents the outer edge of the range incident on the pupil of the lens 203.

As shown in FIGS. 9A and 9B, in the case where light 31 from the illumination 201 is incident on the photomask 202 along the optical axis O, the zeroth order diffracted beam A is incident on the pupil of the lens 203. However, the first order diffracted beams B-G are emitted in greatly inclined directions with respect to the optical axis O, and are not incident on the pupil of the lens 203. Thus, only the zeroth order diffracted beam reaches the resist film 110, and no interference of light occurs. Hence, no image is formed.

Thus, as shown in FIGS. 4 and 10A, the incident direction of the light 31 is inclined from the optical axis O so that the light 31 is made incident on the photomask 202 in an oblique direction. Hence, as shown in FIG. 10B, three diffracted beams A, B, and C are incident on the pupil of the lens 203 and reach the resist film 110. Here, the shift direction and shift amount of the incident direction of the light 31 are selected so that the diffracted beams A, B, and C pass through positions equidistant from the pupil of the lens 203. As a result, as shown in FIG. 11, interference occurs on the image plane. Light portions are formed at positions where the waves constructively interfere with each other, and dark portions are formed at positions where the waves destructively interfere with each other. In consideration of the Fourier transform of the pattern formed on the photomask 202 and the shift amount (ξₛ, ηₛ) of the illumination, the diffracted beam distribution on the pupil plane in this case can be represented by the following equation (13). Here, on the photomask 202, the dimension of the opening pattern and the complex amplitude transmittance of the non-transparent region are preferably set so that the amplitudes of the diffracted beams A, B, and C are equal to each other.

$$\tilde{a} ( f + {ξ}_{s} , g + {η}_{s} ) = A δ \{ f - ( {f}_{a} - {ξ}_{s} ) , g - ( {g}_{a} - {η}_{s} ) \} + B δ \{ f - ( {f}_{b} - {ξ}_{s} ) , g - ( {g}_{b} - {η}_{s} ) \} + C δ \{ f - ( {f}_{c} - {ξ}_{s} ) , g - ( {g}_{c} - {η}_{s} ) \} \qquad ( 13 )$$

In the above equation (13), fₐ, f_{b}, and f_{c} are equivalent to the coordinates shown in FIGS. 9B and 10B. The light intensity distribution in the image formed by the diffracted beams given by the above equation (13) is represented by the following equation (14). The following equation (14) is an imaging equation representing the light intensity distribution in the case where the pattern of the aforementioned modified n-run stagger is formed by three-beam interference.

$$I ( x , y , z ) \approx {A}^{2} + {B}^{2} + {C}^{2} + 2 AB cos [ \begin{matrix}k ( {f}_{a} - {f}_{b} ) x + k ( {g}_{a} - {g}_{b} ) y + \\ k \{ \begin{matrix}\sqrt{1 - {( {f}_{a} - {ξ}_{s} )}^{2} {( {g}_{a} - {η}_{s} )}^{2}} - \\ \sqrt{1 - {( {f}_{b} - {ξ}_{s} )}^{2} - {( {g}_{b} - {η}_{s} )}^{2}}\end{matrix} \} z\end{matrix} ] + 2 BC cos [ \begin{matrix}k ( {f}_{b} - {f}_{c} ) x + k ( {g}_{b} - {g}_{c} ) y + \\ k \{ \begin{matrix}\sqrt{1 - {( {f}_{b} - {ξ}_{s} )}^{2} - {( {g}_{b} - {η}_{s} )}^{2}} - \\ \sqrt{1 - {( {f}_{c} - {ξ}_{s} )}^{2} - {( {g}_{c} - {η}_{s} )}^{2}}\end{matrix} \} z\end{matrix} ] + 2 CA cos [ \begin{matrix}k ( {f}_{c} - {f}_{a} ) x + k ( {g}_{c} - {g}_{a} ) y + \\ k \{ \begin{matrix}\sqrt{1 - {( {f}_{c} - {ξ}_{s} )}^{2} - {( {g}_{c} - {η}_{s} )}^{2}} - \\ \sqrt{1 - {( {f}_{a} - {ξ}_{s} )}^{2} - {( {g}_{a} - {η}_{s} )}^{2}}\end{matrix} \} z\end{matrix} ] \qquad ( 14 )$$

In the above equation (14), the first to third terms on the right hand side represent uniform components independent of x, y, and z. The fourth to sixth terms represent interference waves generated by interference of the diffracted beam A and the diffracted beam B, interference of the diffracted beam B and the diffracted beam C, and interference of the diffracted beam C and the diffracted beam A, respectively. The three diffracted beams form three plane waves, and form light portions and dark portions. For instance, in the case where the resist film 110 (see FIGS. 3 and 4) is made of a positive resist, if the formation target region of the contact hole is located at the position of the light portion, exposure can be performed in good condition. As described above, this exposed portion is removed by development to form a resist mask. This resist mask is used to etch the interlayer insulating film. Thus, a contact hole is formed.

Here, the optimal illumination condition is defined as the illumination condition maximizing the depth of focus. In this case, the optimal illumination condition is the condition such that the coefficient of z becomes zero in the above equation (14), i.e., the condition satisfying the following equations (15) and (16).

(fₐ−ξₛ)²+(gₐ−ηₛ)²=(f_{b}−ξₛ)²+(g_{b}−ηₛ)² (15)

(f_{b}−ξₛ)²+(g_{b}−ηₛ)²=(f_{c}−ξₛ)²+(g_{c}−ηₛ)² (16)

The above equations (15) and (16) are solved for the modified n-run stagger by substitution of the coordinates shown in FIGS. 9B and 10B. This yields the following equations (17) and (18).

$$\begin{matrix}{ξ}_{s} = \frac{λ}{2} ( \frac{1}{{P}_{x}} + ( 1 + α - {α}^{2} ) \frac{{P}_{x}}{{P}_{y}^{2}} ) & ( 17 ) \\ {η}_{s} = \frac{( 2 α - 1 ) λ}{2 {P}_{y}} & ( 18 )\end{matrix}$$

When the shift amount (ξₛ, ηₛ) of the illumination satisfies the above equations (17) and (18), the z component vanishes from the equations representing the optical image. This enables exposure with a large depth of focus and less prone to defocusing.

Typically, the coordinate system of the illumination is represented in the form normalized by the numerical aperture NA. Thus, the shift amount (ξₛ, ηₛ) given by the above equations (17) and (18) is normalized by the numerical aperture NA to obtain coordinates (σₓ, σ_{y}). The optimal illumination condition is represented by the normalized coordinates (σ_{y}, σ_{y}). The coordinates (σ_{y}, σ_{y}) thus normalized are presented in the following equations (19) and (20). They give a theoretical formula of the optimal illumination condition for obtaining the maximum depth of focus.

$$\begin{matrix}{σ}_{x} = \frac{λ}{2 NA} ( \frac{1}{{P}_{x}} + ( 1 + α - {α}^{2} ) \frac{{P}_{x}}{{P}_{y}^{2}} ) & ( 19 ) \\ {σ}_{y} = \frac{( 2 α - 1 ) λ}{2 {NAP}_{y}} & ( 20 )\end{matrix}$$

The foregoing description relates to the case of using the diffracted beams A, B, and C as shown in FIG. 10B under the illumination condition shown in FIG. 10A. On the other hand, the argument similar to the foregoing is also applicable to the case of using the diffracted beams A, B, and D as shown in FIGS. 12A and 12B, and the case of using the diffracted beams A, C, and E as shown in FIGS. 13A and 13B. The coordinates (σ_{y}, σ_{y}) of the bright point in the case shown in FIGS. 12A and 12B are given by the following equations (21) and (22). The coordinates (σ_{y}, σ_{y}) of the bright point in the case shown in FIGS. 13A and 13B are given by the following equations (23) and (24).

$$\begin{matrix}{σ}_{x} = \frac{λ}{2 NA} ( \frac{1}{{P}_{x}} - ( 1 - α ) α \frac{{P}_{x}}{{P}_{y}^{2}} ) & ( 21 ) \\ {σ}_{y} = \frac{λ}{2 {NAP}_{y}} & ( 22 ) \\ {σ}_{x} = \frac{λ}{2 NA} ( \frac{1}{{P}_{x}} - ( 1 - α ) α \frac{{P}_{x}}{{P}_{y}^{2}} ) & ( 23 ) \\ {σ}_{y} = - \frac{λ}{2 {NAP}_{y}} & ( 24 )\end{matrix}$$

The above equations (19) and (20) are the same as the above equations (9) and (10). The above equations (21) and (22) are the same as the above equations (1) and (2). The above equations (23) and (24) are the same as the above equations (5) and (6). Furthermore, point p1 and point p2, point p3 and point p4, and point p5 and point p6 shown in FIG. 5 are located symmetrically with each other with respect to the optical axis O (see FIG. 4). Hence, the above equations (3) and (4) are derived from the above equations (1) and (2). The above equations (7) and (8) are derived from the above equations (5) and (6). The above equations (11) and (12) are derived from the above equations (9) and (10). Thus, the above equations (1)-(12) are derived.

Next, the effect of the embodiment is described.

In the exposure method according to the embodiment, as shown in FIG. 2, point images arranged in the modified n-run stagger can be imaged while ensuring a large depth of focus. In the method for manufacturing a semiconductor device according to the embodiment, the above exposure method can be applied to the resist film 110 to manufacture a NAND flash memory 100 with bit line contacts CB arranged in the modified n-run stagger as shown in FIG. 1. In the NAND flash memory 100, the bit line contacts CB are arranged in the modified n-run stagger. Hence, while suppressing the length D_{y} of the layout region of the bit line contacts CB, the minimum distance between the bit line contacts CB can be ensured, and the arrangement pitch of the bit lines BL can be reduced. As a result, the packing density of the NAND flash memory 100 can be increased.

Next, a second embodiment is described.

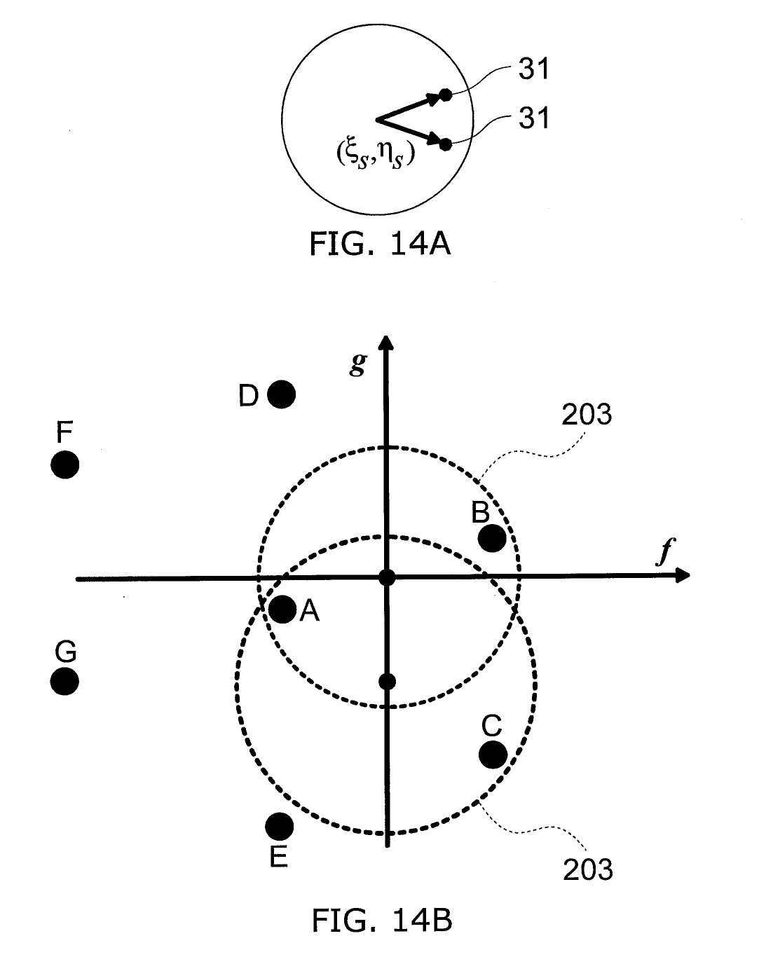

FIG. 14A illustrates an illumination condition of the embodiment. FIG. 14B illustrates the distribution of diffracted beams formed when the photomask of the modified n-run stagger is irradiated with the light shown in FIG. 14A.

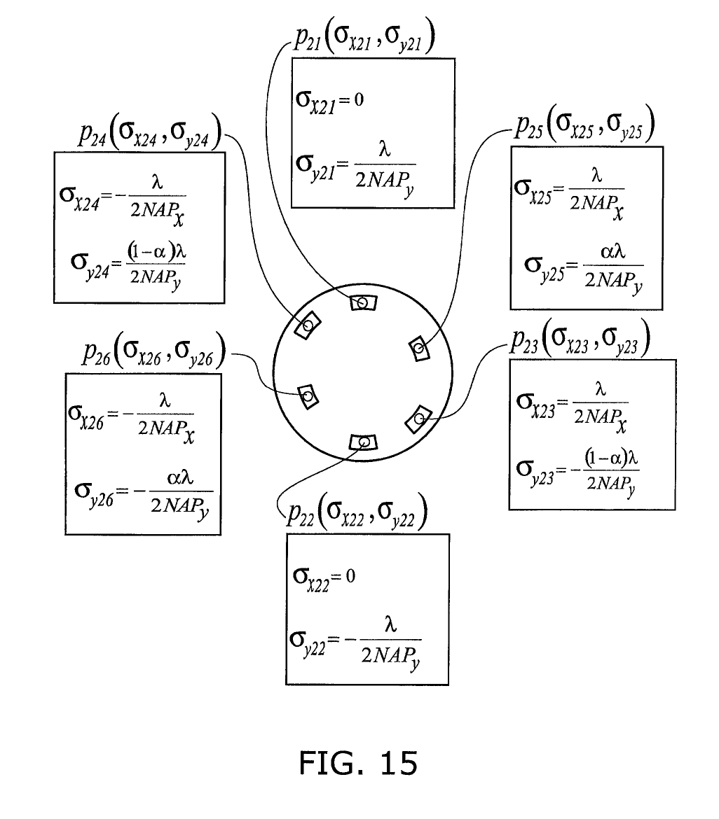

FIG. 15 illustrates an illumination geometry in the exposure optical system of the embodiment.

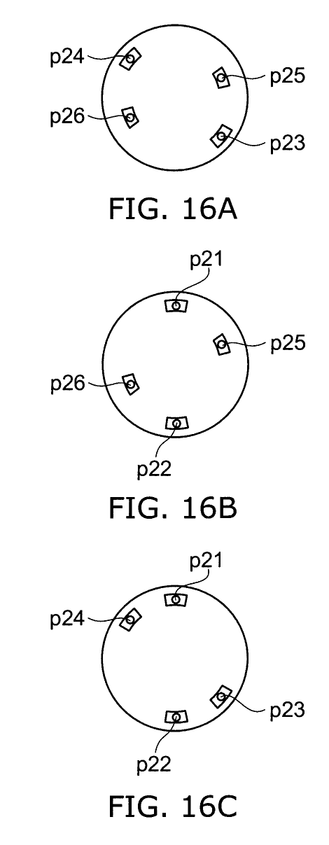

FIGS. 16A to 16C illustrate other illumination geometries in the exposure optical system of the embodiment.

As shown in FIGS. 14A and 14B, in the embodiment, the position of the light emitting region is set so that two of the diffracted beams A-G diffracted by the photomask 202 (see FIG. 4) are incident on the pupil of the lens 203. More specifically, the zeroth order diffracted beam A and one of the first order diffracted beams B-G are made incident on the pupil of the lens 203. Then, two light emitting regions are set to allow such two diffracted beams to be incident on the pupil of the lens 203. For instance, in the example shown in FIGS. 14A and 14B, a light emitting region with the zeroth order diffracted beam A and the first order diffracted beam B incident on the pupil of the lens 203, and a light emitting region with the zeroth order diffracted beam A and the first order diffracted beam C incident on the pupil of the lens 203 are set. Thus, interference of the diffracted beams A and B, and interference of the diffracted beams A and C occur. However, interference of the diffracted beams B and C does not occur. This results in decreasing the contrast of the optical image, but can form a pattern similar to that of the above first embodiment.

There are six possible combinations of the zeroth order diffracted beam A and one first order diffracted beam. These six combinations are examined as in the above first embodiment to determine light emitting regions in the illumination 201. The result is shown in FIG. 15 and the following equations (25)-(36). Then, two or more pairs are selected from among the pair of point p21(σₓ₂₁, σ_{y21}) and point p22(σₓ₂₂, σ_{y22}), the pair of point p23(σₓ₂₃, σ_{y23}) and point p24(σₓ₂₄, σ_{y24}), and the pair of point p25(σₓ₂₅, σ_{y25}) and point p26(σₓ₂₆, σ_{y26}). In each selected pair, a region including at least one point is used as a light emitting region.

$$\begin{matrix}{σ}_{x 21} = 0 & ( 25 ) \\ {σ}_{y 21} = \frac{λ}{2 {NAP}_{y}} & ( 26 ) \\ {σ}_{x 22} = 0 & ( 27 ) \\ {σ}_{y 22} = - \frac{λ}{2 {NAP}_{y}} & ( 28 ) \\ {σ}_{x 23} = \frac{λ}{2 {NAP}_{x}} & ( 29 ) \\ {σ}_{y 23} = - \frac{( 1 - α ) λ}{2 {NAP}_{y}} & ( 30 ) \\ {σ}_{x 24} = - \frac{λ}{2 {NAP}_{x}} & ( 31 ) \\ {σ}_{y 24} = \frac{( 1 - α ) λ}{2 {NAP}_{y}} & ( 32 ) \\ {σ}_{x 25} = \frac{λ}{2 {NAP}_{x}} & ( 33 ) \\ {σ}_{y 25} = \frac{αλ}{2 {NAP}_{y}} & ( 34 ) \\ {σ}_{x 26} = - \frac{λ}{2 {NAP}_{x}} & ( 35 ) \\ {σ}_{y 26} = - \frac{αλ}{2 {NAP}_{y}} & ( 36 )\end{matrix}$$

For instance, as shown in FIG. 15, six regions respectively including points p21-p26 may be used as light emitting regions. Alternatively, as shown in FIGS. 16A to 16C, four regions each including a point belonging to two of the above three pairs, two points for each pair, may be used as light emitting regions. The illumination geometries as shown in FIGS. 15 and 16A to 16C allow the light emitting regions to be symmetric with respect to the optical axis O (see FIG. 4) of the exposure optical system 200. This improves the symmetry of the shape of the contact hole. Furthermore, a total of three or two regions each including a point belonging to two of the above three pairs, at least one of two points for each pair, may be used as light emitting regions. Also in this case, the modified 5-run stagger can be realized. The exposure method and the method for manufacturing a semiconductor device of the embodiment other than the foregoing are similar to those of the above first embodiment.

According to the embodiment, it is only necessary to cause two diffracted beams to be incident on the pupil of the lens 203. Thus, the angle between the diffracted beams incident on the pupil can be made larger than that in the case where three diffracted beams are made incident on the pupil as in the above first embodiment. That is, the pattern of the photomask 202 can be made finer. This enables manufacturing of a semiconductor device with higher packing density. The effect of the embodiment other than the foregoing is similar to that of the above first embodiment.

The embodiments described above can realize an exposure method and a method for manufacturing a semiconductor device in which the packing density of the semiconductor device can be increased.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An exposure method comprising:
applying light to a photomask by an illumination;
converging diffracted beams emitted from the photomask by a lens; and
imaging a plurality of point images on an exposure surface,
on the photomask, a light transmitting region being formed at a lattice point represented by nonorthogonal unit cell vectors, and
in the illumination, a light emitting region being set so that three or more of the diffracted beams pass through positions equidistant from center of a pupil of the lens.

2. The method according to claim 1, wherein
on the exposure surface, the point images are located at part of the lattice points of a lattice extending in first and second directions orthogonal to each other, and
the unit cell vectors, denoted by a and b, are given by
a=(Pₓ, 0), and
b=((1−a)×Pₓ, P_{y}),
where Pₓ is an arrangement pitch of the point images in the first direction, P_{y} is an arrangement pitch of the lattice points in the second direction, and a is a real number greater than 0 and less than 1.

3. An exposure method comprising:
applying light to a photomask by an illumination;
converging diffracted beams emitted from the photomask by a lens; and
imaging a plurality of point images on an exposure surface,
on the photomask, a light transmitting region being formed at a lattice point represented by nonorthogonal unit cell vectors, and
in the illumination, a light emitting region being set so that two or more pairs of the diffracted beams are incident on a pupil of the lens and that the two diffracted beams belonging to each of the pairs pass through positions equidistant from center of the pupil of the lens.

4. The method according to claim 3, wherein
on the exposure surface, the point images are located at part of the lattice points of a lattice extending in first and second directions orthogonal to each other, and
the unit cell vectors, denoted by a and b, are given by
a=(Pₓ, 0), and
b=((1−a)×Pₓ, P_{y}),
where Pₓ is an arrangement pitch of the point images in the first direction, P_{y} is an arrangement pitch of the lattice points in the second direction, and a is a real number greater than 0 and less than 1.

5. An exposure method comprising:
performing exposure of a plurality of point images on an exposure surface,
on the exposure surface, the point images being located at part of lattice points of a lattice extending in first and second directions orthogonal to each other, and
a light emitting region of an illumination being one or more regions selected from the group consisting of a region including a first point (σₓ₁₁, σ_{y11}), a region including a second point (σₓ₁₂, σ_{y12}), a region including a third point (σₓ₁₃, σ_{y13}), a region including a fourth point (σₓ₁₄, σ_{y14}), a region including a fifth point (σₓ₁₅, σ_{y15}), and a region including a sixth point (σₓ₁₆, σ_{y16}),
where an arrangement pitch of the point images in the first direction is Pₓ, an arrangement pitch of the lattice points in the second direction is P_{y}, a distance in the first direction between one of the point images and another of the point images displaced by the P_{y} in the second direction from the one point image is a×Pₓ (a being a real number satisfying 0<a<1), a wavelength of light used for the exposure is λ, and a numerical aperture of a lens used for the exposure is NA.
$$\begin{matrix}{σ}_{x 11} = \frac{λ}{2 NA} ( \frac{1}{{P}_{x}} - ( 1 - α ) α \frac{{P}_{x}}{{P}_{y}^{2}} ) \\ {σ}_{y 11} = \frac{λ}{2 {NAP}_{y}} \\ {σ}_{x 12} = - \frac{λ}{2 NA} ( \frac{1}{{P}_{x}} - ( 1 - α ) α \frac{{P}_{x}}{{P}_{y}^{2}} ) \\ {σ}_{{y}_{12}} = - \frac{λ}{2 {NAP}_{y}} \\ {σ}_{x 13} = \frac{λ}{2 NA} ( \frac{1}{{P}_{x}} - ( 1 - α ) α \frac{{P}_{x}}{{P}_{y}^{2}} ) \\ {σ}_{y 13} = - \frac{λ}{2 {NAP}_{y}} \\ {σ}_{x 14} = - \frac{λ}{2 NA} ( \frac{1}{{P}_{x}} - ( 1 - α ) α \frac{{P}_{x}}{{P}_{y}^{2}} ) \\ {σ}_{y 14} = \frac{λ}{2 {NAP}_{y}} \\ {σ}_{x 15} = \frac{λ}{2 NA} ( \frac{1}{{P}_{x}} + ( 1 + α - {α}^{2} ) \frac{{P}_{x}}{{P}_{y}^{2}} ) \\ {σ}_{y 15} = \frac{( 2 α - 1 ) λ}{2 {NAP}_{y}} \\ {σ}_{x 16} = - \frac{λ}{2 NA} ( \frac{1}{{P}_{x}} + ( 1 + α - {α}^{2} ) \frac{{P}_{x}}{{P}_{y}^{2}} ) \\ {σ}_{y 16} = - \frac{( 2 α - 1 ) λ}{2 {NAP}_{y}}\end{matrix}$$

6. The method according to claim 5, wherein the light emitting region is all the regions belonging to one or more pairs among a pair of the region including the first point and the region including the second point, a pair of the region including the third point and the region including the fourth point, and a pair of the region including the fifth point and the region including the sixth point.

7. An exposure method comprising:
performing exposure of a plurality of point images on an exposure surface,
on the exposure surface, the point images being located at part of lattice points of a lattice extending in first and second directions orthogonal to each other, and
a light emitting region of an illumination being a region including at least one point in each of two or more pairs selected from the group consisting of a pair of a first point (σₓ₂₁, σ_{y21}) and a second point (σₓ₂₂, σ_{y22}), a pair of a third point (σₓ₂₃, σ_{y23}) and a fourth point (σₓ₂₄, σ_{y24}), and a pair of a fifth point (σₓ₂₅, σ_{y25}) and a sixth point (σₓ₂₆, σ_{y26}),
where an arrangement pitch of the point images in the first direction is Pₓ, an arrangement pitch of the lattice points in the second direction is P_{y}, a distance in the first direction between one of the point images and another of the point images displaced by the P_{y} in the second direction from the one point image is a×Pₓ (a being a real number satisfying 0<a<1), a wavelength of light used for the exposure is λ, and a numerical aperture of a lens used for the exposure is NA.
$$\begin{matrix}{σ}_{x 21} = 0 \\ {σ}_{y 21} = \frac{λ}{2 {NAP}_{y}} \\ {σ}_{x 22} = 0 \\ {σ}_{y 22} = - \frac{λ}{2 {NAP}_{y}} \\ {σ}_{x 23} = \frac{λ}{2 {NAP}_{x}} \\ {σ}_{y 23} = - \frac{( 1 - α ) λ}{2 {NAP}_{y}} \\ {σ}_{x 24} = - \frac{λ}{2 {NAP}_{x}} \\ {σ}_{y 24} = \frac{( 1 - α ) λ}{2 {NAP}_{y}} \\ {σ}_{x 25} = \frac{λ}{2 {NAP}_{x}} \\ {σ}_{y 25} = \frac{αλ}{2 {NAP}_{y}} \\ {σ}_{x 26} = - \frac{λ}{2 {NAP}_{x}} \\ {σ}_{y 26} = - \frac{αλ}{2 {NAP}_{y}}\end{matrix}$$

8. The method according to claim 7, wherein the light emitting region is a region including each point belonging to the selected two or more pairs.

9. The method according to claim 2, wherein the a is a real number represented by a=m/n, where m and n are natural numbers.

10. A method for manufacturing a semiconductor device, comprising:
forming an interlayer insulating film on a substrate;
forming a resist film on the interlayer insulating film;
performing exposure on the resist film;
developing the resist film;
forming a contact hole in the interlayer insulating film by etching using the developed resist film as a mask; and
forming a contact by burying a metal in the contact hole,
the performing exposure including applying light to a photomask by an illumination, converging diffracted beams emitted from the photomask by a lens, and imaging a plurality of point images on an exposure surface,
on the photomask, a light transmitting region being formed at a lattice point represented by nonorthogonal unit cell vectors,
in the illumination, a light emitting region being set so that three or more of the diffracted beams pass through positions equidistant from center of a pupil of the lens, and
each of the point images being a region where the contact hole is to be formed.

11. A method for manufacturing a semiconductor device, comprising:
forming an interlayer insulating film on a substrate;
forming a resist film on the interlayer insulating film;
performing exposure on the resist film;
developing the resist film;
forming a contact hole in the interlayer insulating film by etching using the developed resist film as a mask; and
forming a contact by burying a metal in the contact hole,
the performing exposure including applying light to a photomask by an illumination, converging diffracted beams emitted from the photomask by a lens, and imaging a plurality of point images on an exposure surface,
on the photomask, a light transmitting region being formed at a lattice point represented by nonorthogonal unit cell vectors,
in the illumination, a light emitting region being set so that two or more pairs of the diffracted beams are incident on a pupil of the lens and that the two diffracted beams belonging to each of the pairs pass through positions equidistant from center of the pupil of the lens, and
each of the point images being a region where the contact hole is to be formed.

12. A method for manufacturing a semiconductor device, comprising:
forming an interlayer insulating film on a substrate;
forming a resist film on the interlayer insulating film;
performing exposure on the resist film;
developing the resist film;
forming a contact hole in the interlayer insulating film by etching using the developed resist film as a mask; and
forming a contact by burying a metal in the contact hole,
the performing exposure including applying light to a photomask by an illumination, converging diffracted beams emitted from the photomask by a lens, and imaging a plurality of point images on an exposure surface,
on the photomask, a light transmitting region being formed at a lattice point represented by nonorthogonal unit cell vectors,
in the illumination, a light emitting region being set so that three or more of the diffracted beams pass through positions equidistant from center of a pupil of the lens,
on the exposure surface, the point images being located at part of the lattice points of a lattice extending in first and second directions orthogonal to each other,
the unit cell vectors, denoted by a and b, being given by a=(Pₓ, 0) and b=((1−a)×Pₓ, P_{y}), where Pₓ is arrangement pitch of the point images in the first direction, P_{y} is arrangement pitch of the lattice points in the second direction, and a is a real number greater than 0 and less than 1, and
the point image being a region where the contact hole is to be formed.

13. A method for manufacturing a semiconductor device, comprising:
forming an interlayer insulating film on a substrate;
forming a resist film on the interlayer insulating film;
performing exposure on the resist film;
developing the resist film;
forming a contact hole in the interlayer insulating film by etching using the developed resist film as a mask; and
forming a contact by burying a metal in the contact hole,
the performing exposure including applying light to a photomask by an illumination, converging diffracted beams emitted from the photomask by a lens, and imaging a plurality of point images on an exposure surface,
on the photomask, a light transmitting region being formed at a lattice point represented by nonorthogonal unit cell vectors,
in the illumination, a light emitting region being set so that two or more pairs of the diffracted beams are incident on a pupil of the lens and that the two diffracted beams belonging to each of the pairs pass through positions equidistant from center of the pupil of the lens,
on the exposure surface, the point images being located at part of the lattice points of a lattice extending in first and second directions orthogonal to each other,
the unit cell vectors, denoted by a and b, being given by a=(Pₓ, 0) and b=((1−a)×Pₓ, P_{y}), where P_{X} is an arrangement pitch of the point images in the first direction, P_{y} is an arrangement pitch of the lattice points in the second direction, and a is a real number greater than 0 and less than 1, and
each of the point images being a region where the contact hole is to be formed.

14. A method for manufacturing a semiconductor device, comprising:
forming an interlayer insulating film on a substrate;
forming a resist film on the interlayer insulating film;
performing exposure on the resist film;
developing the resist film;
forming a contact hole in the interlayer insulating film by etching using the developed resist film as a mask; and
forming a contact by burying a metal in the contact hole,
the performing exposure including performing exposure of a plurality of point images on an exposure surface,
on the exposure surface, the point images being located at part of lattice points of a lattice extending in first and second directions orthogonal to each other,
a light emitting region of an illumination being one or more regions selected from the group consisting of a region including a first point (σₓ₁₁, σ_{y11}), a region including a second point (σₓ₁₂, σ_{y12}), a region including a third point (σₓ₁₃, σ_{y13}), a region including a fourth point (σₓ₁₄, σ_{y14}), a region including a fifth point (σₓ₁₅, σ_{yl5}), and a region including a sixth point (σₓ₁₆, σ_{yl6),}
where an arrangement pitch of the point images in the first direction is Pₓ, an arrangement pitch of the lattice points in the second direction is P_{y}, a distance in the first direction between one of the point images and another of the point images displaced by the P_{y} in the second direction from the one point image is a×Pₓ (a being a real number satisfying 0<a<1), a wavelength of light used for the exposure is λ, and a numerical aperture of a lens used for the exposure is NA, and
each of the point images being a region where the contact hole is to be formed.
$$\begin{matrix}{σ}_{x 11} = \frac{λ}{2 NA} ( \frac{1}{{P}_{x}} - ( 1 - α ) α \frac{{P}_{x}}{{P}_{y}^{2}} ) \\ {σ}_{y 11} = \frac{λ}{2 {NAP}_{y}} \\ {σ}_{x 12} = - \frac{λ}{2 NA} ( \frac{1}{{P}_{x}} - ( 1 - α ) α \frac{{P}_{x}}{{P}_{y}^{2}} ) \\ {σ}_{{y}_{12}} = - \frac{λ}{2 {NAP}_{y}} \\ {σ}_{x 13} = \frac{λ}{2 NA} ( \frac{1}{{P}_{x}} - ( 1 - α ) α \frac{{P}_{x}}{{P}_{y}^{2}} ) \\ {σ}_{y 13} = - \frac{λ}{2 {NAP}_{y}} \\ {σ}_{x 14} = - \frac{λ}{2 NA} ( \frac{1}{{P}_{x}} - ( 1 - α ) α \frac{{P}_{x}}{{P}_{y}^{2}} ) \\ {σ}_{y 14} = \frac{λ}{2 {NAP}_{y}} \\ {σ}_{x 15} = \frac{λ}{2 NA} ( \frac{1}{{P}_{x}} + ( 1 + α - {α}^{2} ) \frac{{P}_{x}}{{P}_{y}^{2}} ) \\ {σ}_{y 15} = \frac{( 2 α - 1 ) λ}{2 {NAP}_{y}} \\ {σ}_{x 16} = - \frac{λ}{2 NA} ( \frac{1}{{P}_{x}} + ( 1 + α - {α}^{2} ) \frac{{P}_{x}}{{P}_{y}^{2}} ) \\ {σ}_{y 16} = - \frac{( 2 α - 1 ) λ}{2 {NAP}_{y}}\end{matrix}$$

15. The method according to claim 14, further comprising:
forming a wiring on the interlayer insulating film, the wiring extending in the second direction, arranged at a pitch of Pₓ/n (n being a natural number of two or more) along the first direction, and connected to the contact,
a second contact formed at a position of the another of the point images being connected to a m-th wiring (m being a natural number of n or less) as viewed from a first wiring connected with a first contact formed at a position of the one of the point images, and
the a is given by a=m/n.

16. The method according to claim 15, wherein
the semiconductor device is a NAND flash memory, and
the wiring is a bit line.

17. A method for manufacturing a semiconductor device, comprising:
forming an interlayer insulating film on a substrate;
forming a resist film on the interlayer insulating film;
performing exposure on the resist film;
developing the resist film;
forming a contact hole in the interlayer insulating film by etching using the developed resist film as a mask; and
forming a contact by burying a metal in the contact hole,
the performing exposure including performing exposure of a plurality of point images on an exposure surface,
on the exposure surface, the point images being located at part of lattice points of a lattice extending in first and second directions orthogonal to each other,
a light emitting region of an illumination being a region including at least one point in each of two or more pairs selected from the group consisting of a pair of a first point (σₓ₂₁, σ_{y21}) and a second point (σₓ₂₂, σ_{y22}), a pair of a third point (σₓ₂₃, σ_{y23}) and a fourth point (σₓ₂₄, σ_{y24}), and a pair of a fifth point (σₓ₂₅, σ_{y25}) and a sixth point (σₓ₂₆, σ_{y26}),
where an arrangement pitch of the point images in the first direction is Pₓ, an arrangement pitch of the lattice points in the second direction is P_{y}, a distance in the first direction between one of the point images and another of the point images displaced by the P_{y} in the second direction from the one point image is a×Pₓ (a being a real number satisfying 0<a<1), a wavelength of light used for the exposure is λ, and a numerical aperture of a lens used for the exposure is NA, and
each of the point image being a region where the contact hole is to be formed.
$$\begin{matrix}{σ}_{x 21} = 0 \\ {σ}_{y 21} = \frac{λ}{2 {NAP}_{y}} \\ {σ}_{x 22} = 0 \\ {σ}_{y 22} = - \frac{λ}{2 {NAP}_{y}} \\ {σ}_{x 23} = \frac{λ}{2 {NAP}_{x}} \\ {σ}_{y 23} = - \frac{( 1 - α ) λ}{2 {NAP}_{y}} \\ {σ}_{x 24} = - \frac{λ}{2 {NAP}_{x}} \\ {σ}_{y 24} = \frac{( 1 - α ) λ}{2 {NAP}_{y}} \\ {σ}_{x 25} = \frac{λ}{2 {NAP}_{x}} \\ {σ}_{y 25} = \frac{αλ}{2 {NAP}_{y}} \\ {σ}_{x 26} = - \frac{λ}{2 {NAP}_{x}} \\ {σ}_{y 26} = - \frac{αλ}{2 {NAP}_{y}}\end{matrix}$$

18. The method according to claim 17, further comprising:
forming a wiring on the interlayer insulating film, the wiring extending in the second direction, arranged at a pitch of Pₓ/n (n being a natural number of two or more) along the first direction, and connected to the contact,
a second contact formed at a position of the another of the point images being connected to a m-th wiring (m being a natural number of n or less) as viewed from a first wiring connected with a first contact formed at a position of the one of the point images, and
the a is given by a=m/n.

19. The method according to claim 18, wherein
the semiconductor device is a NAND flash memory, and
the wiring is a bit line.
